(19) United States
(12) Patent Application Publication
(10) Pub. No.: US 2024/0024807 A1
(43) Pub. Date: Jan. 25, 2024

(54) GAS FILTER DEVICE AND RETICLE CARRIER PROVIDED WITH THE SAME

(71) Applicant: GUDENG PRECISION INDUSTRIAL CO., LTD., New Taipei City (TW)

(72) Inventors: Ming-Chien CHIU, New Taipei City (TW); Chia-Ho CHUANG, New Taipei City (TW); Hsin-Min HSUEH, New Taipei City (TW); Shu-Hung LIN, New Taipei City (TW)

(21) Appl. No.: 18/070,550

(22) Filed: Nov. 29, 2022

Related U.S. Application Data
(60) Provisional application No. 63/390,353, filed on Jul. 19, 2022.

(51) Int. Cl. B01D 46/00

(52) U.S. Cl. CPC B01D 46/0005; B01D 46/0001; B01D 2275/30; B01D 2239/1216; B01D 2265/06

(57) ABSTRACT

The present invention discloses a gas filter device detachably mounted onto a reticle carrier. The gas filter device includes at least one porous diffusion member and a plurality of connecting members. The porous diffusion member is detachably connected to the reticle carrier by the plurality of connecting members, so that the porous diffusion member is restricted on the reticle carrier to provide filtering function.

### CROSS-REFERENCE TO RELATED APPLICATION

This application claims the benefit of U.S. Provisional Application Ser. No. 63/390,353 and filed on Jul. 19, 2022 of which are expressly incorporated by reference herein in their entirety.

### BACKGROUND OF THE INVENTION

### Field of the Invention

The present invention relates to a reticle carrier for storing and transporting reticles, and more particularly to a reticle carrier having a gas filter device to allow air to enter the reticle carrier through the gas filter device.

### Description of the Prior Art

To maintain the cleanliness of substrates, such as reticles, the reticles are generally stored in a so-called reticle carrier, for example, a mask package or a reticle standard mechanical interface (SMIF) pod, so as to prevent micro particles in process environments from attaching to surfaces of the reticles.

FIG. 1 shows an example of a conventional reticle carrier, which is a dual pod and usually serves as a reticle SMIF pod. The dual pod includes an outer pod (10) and an inner pod (20) accommodated in the outer pod (10). The outer pod (10) has a cover (11) and a base (12), and the inner pod (20) also has a cover (22) and a base (21). A reticle (R) is stored on the base (21) of the inner pod (20), which is sealed by the cover (22) to form a sealed storage. The inner pod (20) accommodated in the outer pod (10) may be transported by an overhead hoist transport (OHT) system. Although not shown, the outer pod (10) and the inner pod (20) may further include other elements, such as a sealing element, a locking device and a structural limiting element.

Conventionally, an upper surface of the cover (22) of the inner pod (20) is provided with a perforated cover and a filter membrane located between the upper surface and the perforated cover. The filter membrane is usually a flexible sheet made of polytetrafluoroethylene (PTFE) or non-woven fabric. Thus, air is allowed to enter an accommodation space defined by the cover (22) and the base (21) from outside the inner pod through the filter membrane. The filter membrane filters out micro particles in the air, leaving clean and pure air to enter the accommodation space to perform a gas exchange or purifying function.

In semiconductor processes, the dual pod frequently needs to undergo processes such as vacuuming, gas exchange and gas backfilling in response to different objects. In the case of a pressure difference between the inside and the outside the inner pod (20), dry air admitted into the outer pod flows into the reticle accommodation space of the inner pod (20) through the filter membrane of the inner pod (20). Or, in the case of a pressure difference between the inside and the outside the inner pod (20), a gas in the reticle accommodation space is discharged through the filter membrane. Thus, the filter membrane primarily blocks particles that potentially contaminate the reticle outside the inner pod (20).

However, the above conventional filter membrane suffers from certain issues. Due to the very small thickness and the flexible structural property of such filter membrane, when there is a change in the pressure difference between the inside and the outside the inner pod (20), for example, while an airflow enters or leaves the reticle accommodation space of the inner pod through the filter device or during repeated exchange between the inside and the outside, vibration of the filter membrane is generated between the perforated cover and the cover (22) due to its structural property. The vibrated filter membrane then rubs against peripheral metal components (for example, a bottom surface of a recess, a support member or the perforated cover), such that damage can be easily caused to further produce micro particles that fall into the reticle accommodation space. Moreover, the dual pod needs to be washed and cleansed once having been used in semiconductor processing equipment for a certain period of time. The filter membrane is also susceptible to damage and peeling off during such washing and cleansing operation, similarly further producing micro particles that fall into the reticle accommodation space.

Thus, the conventional filter membrane accounts for a potential risk factor that contaminates reticles. There is a need to develop a filter device capable of reducing contamination risks without jeopardizing the filtering function of the filter device so as to enhance the level of protection for a reticle carrier.

### SUMMARY OF THE INVENTION

It is an object of the present invention to provide a gas filter device detachably mounted onto a reticle carrier. The gas filter device includes: a frame, having at least one hollow, the frame detachably connected to the reticle carrier; and at least one porous diffusion member, having a shape matching the at least one hollow of the frame to thereby stably securing the at least one porous diffusion member to the frame. When the frame is connected to the reticle carrier, the at least one porous diffusion member is positioned on the reticle carrier by the frame, such that an internal accommodation space of the reticle carrier communicates with an outside of the reticle carrier through the at least one porous diffusion member.

In one specific embodiment, the frame has a plurality of hollows, each of the hollows is fan-shaped, and the plurality of hollows are in an arrangement of central symmetric.

In one specific embodiment, the frame has an outer skeleton and at least one inner skeleton connected to the outer skeleton. The outer skeleton and the inner skeleton define the hollow in between. The outer skeleton includes a plurality of connecting members which individually coordinate with a locking member, such that the outer skeleton is detachably connected to a cover of the reticle carrier. The inner skeleton is used to engage with the porous diffusion member.

In one specific embodiment, at least one coupling member is provided on an inside of the inner skeleton. The coupling member restricts edges of the porous diffusion member to prevent the porous diffusion member from detaching from the hollow.

In one specific embodiment, the inside of the inner skeleton includes at least one support member connected to the coupling member. The support member is embedded into the porous diffusion member to prevent the porous diffusion member from detaching from the hollow.

In one specific embodiment, the at least one coupling member and an upper surface or a lower surface of the frame appear as a discontinuous stepped structure, and the porous diffusion member is engaged with the coupling member of the inner skeleton by means of sintering.

In one specific embodiment, the at least one porous diffusion member has an upper surface, a lower surface, and a thickness extending between the upper surface and the lower surface, wherein the thickness ranges between 0.1 mm and 3.0 mm.

In one specific embodiment, the at least one porous diffusion member is formed by means of sintering a porous powder at a sintering temperature ranging between 210° C. and 240° C.

In one specific embodiment, a diameter of each pore or an average pore diameter of the at least one porous diffusion member ranges between 0.1 μm and μm.

It is another object of the present invention to provide a reticle carrier including a cover, a base and the above gas filter device. The gas filter device is detachably connected to the cover.

It is yet another object of the present invention to provide a gas filter device detachably mounted onto a reticle carrier. The gas filter device includes: a porous diffusion member, having a panel and a plurality of connecting members located on an outer edge of the panel, the plurality of connecting members respectively coordinating with a plurality of locking members such that the porous diffusion member is detachably connected to the reticle carrier by the plurality of connecting members. An internal accommodation space of the reticle carrier communicates with an outside of the reticle carrier through the porous diffusion member. The panel and the plurality of connecting members of the porous diffusion member are integrally formed.

It is yet another object of the present invention to provide a reticle carrier including: a cover and a base, defining an accommodation space, the cover penetrated by an air passage, the accommodation space communicating with an outside of the reticle carrier through the air passage; and a porous diffusion member, detachably connected to the cover of the reticle carrier, the porous diffusion member communicating with the air passage such that air entering the accommodation space through the air passage is filtered by the porous diffusion member.

### BRIEF DESCRIPTION OF THE DRAWINGS

Reference can be made to the drawings and description below to better understand the present invention. Non-limiting and non-exhaustive embodiments are described with reference to the drawings below. It is to be noted that the components in the drawings are not necessarily drawn to their actual sizes, and are depicted to focus on the description on structures and principles.

FIG. 1 is an exploded diagram of a conventional dual pod.

FIG. 2A is a gas filter device according to a first embodiment of the present invention.

FIG. 2B is an exploded diagram of the first embodiment.

FIG. 2C is an enlarged partial diagram of a cover.

FIG. 2D is a further exploded diagram of the first embodiment.

FIG. 2E is an enlarged diagram of a connecting member of a frame.

FIG. 2F is an enlarged partial diagram of a top of a frame.

FIG. 2G is an enlarged partial diagram of a bottom of a frame.

FIG. 2H is a member diagram along a member line A-A in FIG. 2D.

FIG. 2I is a member diagram along a member line B-B in FIG. 2D.

FIG. 2J to FIG. 2K are other variation examples combining a porous diffusion member and a coupling member.

FIG. 3A is a gas filter device according to a second embodiment of the present invention.

FIG. 3B is an exploded diagram of the second embodiment.

FIG. 3C is another variation of the second embodiment.

FIG. 4A is a configuration example of a gas backfilling experiment.

FIG. 4B is a diagram of a gas backfilling experiment and test, showing dropping curves of humidity levels of a reticle carrier of the present invention and a conventional reticle carrier.

FIG. 5A is a configuration example of a gas exhaustion experiment.

FIG. 5B is a diagram of a gas exhaustion experiment and test, showing changes in pressure differences between the inside and the outside of a reticle carrier of the present invention and a conventional reticle carrier.

### DETAILED DESCRIPTION OF THE EMBODIMENTS

To better describe the present invention, specific examples and specific embodiments are given with the accompanying drawings below. However, the subject matter of the application may be specifically implemented in various different forms, and the construction covered or asserted by the subject matter of the application is not limited to any exemplary specific embodiments disclosed in the detailed description of the application; it should be understood that the specific embodiments are non-limiting and are not to be construed as restrictive. Similarly, the present invention is to provide a reasonably broad scope for the subject matter applied or covered by the subject matter. In addition, the asserted subject matter may be implemented in form of a method, device or system. Thus, the specific embodiments may be embodied by any combination (non-software known) of such as hardware, software and firmware.

The expression “one embodiment” used in the literature of the application does not necessarily refer to the same specific embodiment, and the expression “other/another (some/certain) embodiments” used in the literature of the application does not necessarily refer to different specific embodiments. The object of the above is, for example, to include a combination of all or part of the exemplary specific embodiments by the subject matter set forth.

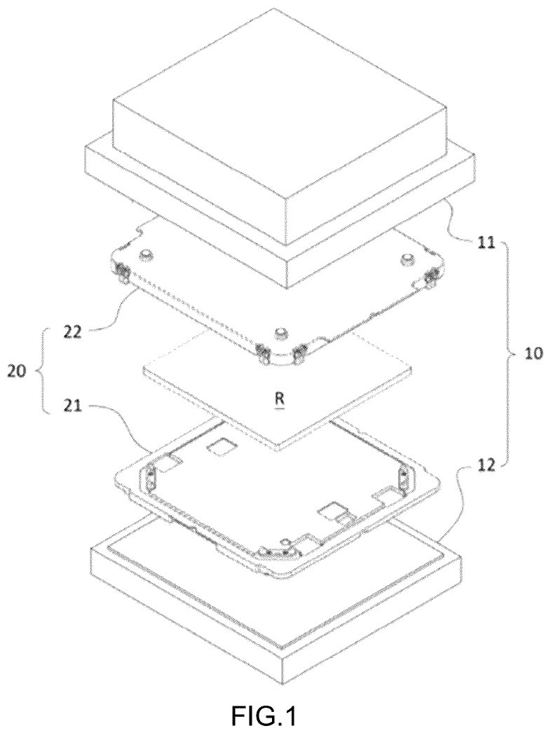

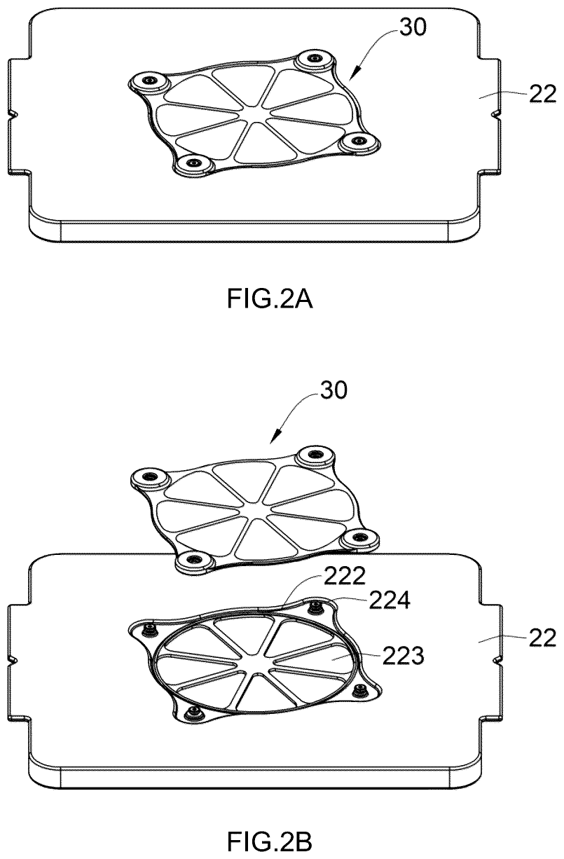

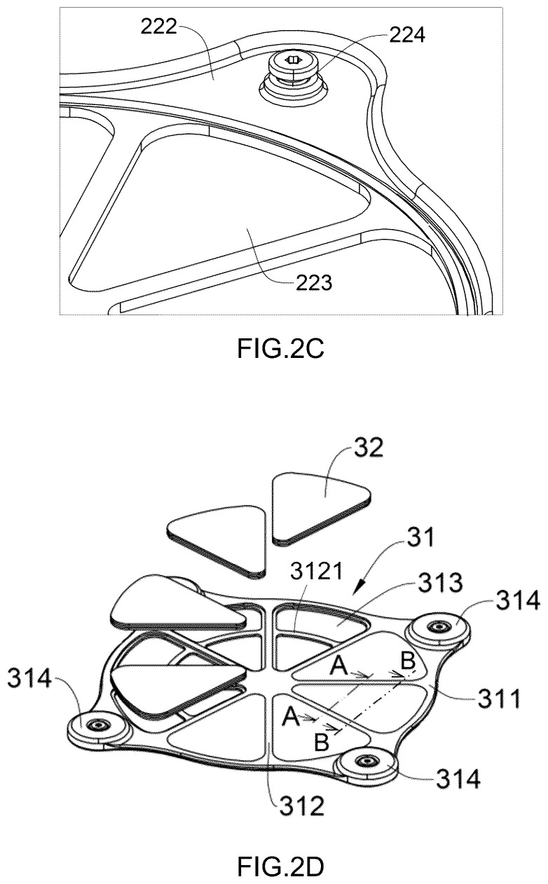

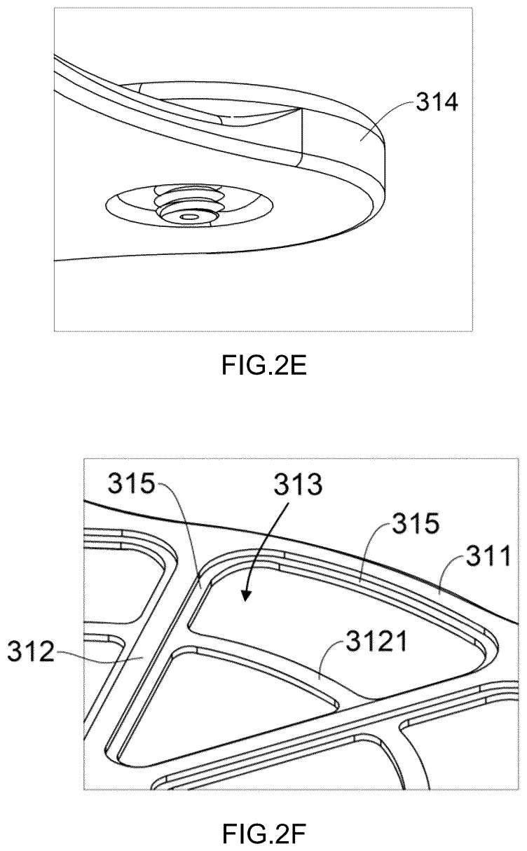

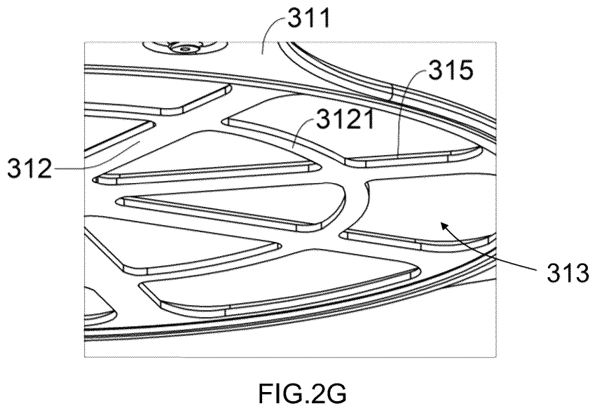

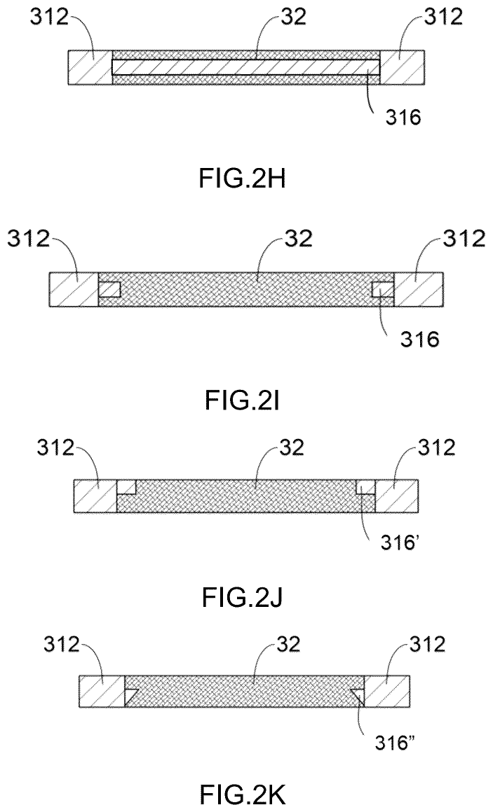

FIG. 2A and FIG. 2B show a gas filter device (30) according to a first embodiment of the present invention. The gas filter device (30) is detachably connected to a cover (22) of a reticle carrier. Although a base of the reticle carrier is not shown, related details can be understood by a person skilled in the art with reference to the base (21) in FIG. 1.

As shown in FIG. 2B, a recess (222) matching the gas filter device (30) is formed on an upper surface of the cover (22). The recess (222) is defined by a bottom surface lower than the upper surface of the cover (22), and the bottom has a shape that matches the shape of the gas filter device (30). For example, the recess (222) of the first embodiment has a centrally symmetric shape with four outward extending corners. Four connecting members (224) are respectively located on the four corners of the bottom surface, and are used to connect the gas filter device (30). Also referring to FIG. 2C showing an enlarged diagram of the connecting member (224), it is seen that the connecting member (224) is a structure raised from the bottom surface of the recess (222) and has a screw hole formed for inserting by a screw. The screw hole does not penetrate the lower surface of the cover (22) so as to ensure airtightness of the cover (22).

FIG. 2D shows that the gas filter device (30) is primarily formed by a frame (31) and a plurality of porous diffusion members (32).

The frame (31) primarily formed by an outer skeleton (311) and an inner skeleton (312). The outer skeleton (311) is fundamentally a ring structure, and the inner skeleton (312) is a radial structure formed by a plurality of beams. To reinforce the overall structural strength, a support member (3121) bridges between adjacent beams of the inner skeleton (312). An inner side of the outer skeleton (311) is connected to an outer side of the inner skeleton (312) to define a structure of a hollow (313), wherein the number of the hollows (313) changes according to the designs of the outer skeleton (311) and the inner skeleton (312). In the first embodiment, taking a plurality of hollows (313) for example, each of these hollows (313) is fan-shaped and all are symmetrically arranged about a center. Each hollow (313) may be further divided into two hollow portions by the support member (3121). A plurality of connecting members (314) are provided on an outer side of the outer skeleton (311) to coordinate with the connecting members (224) of the cover (22). The connecting members (314) and the connecting members (224) may be removed or locked with coordination of locking members, which are, are for example but not limited to, screw elements. The shape of the frame (31) is defined by the outer skeleton (311) and the connecting members (314), such that the frame (31) can be placed at the recess (222) on the upper surface of the cover (22). FIG. 2E shows a perspective from a bottom of the connecting member (314), wherein the bottom of the connecting member (314) has a recess formed to coordinate with the connecting member (224) of the cover (22). As shown, when the connecting member (314) is provided with a screw, an end of the screw protrudes downward from the recess. The designs of the recess on the bottom of the connecting member (314) and the raised structure of the connecting member (224) are beneficial for positioning the gas filter device (30) on the cover (22), hence ensuring that the screw hole of the upper connecting member (314) is aligned with the screw hole of the lower connecting member (224).

Again referring to FIG. 2D, the porous diffusion member (32) has an upper surface, a lower surface, and a thickness extending between the upper surface and the lower surface, wherein the thickness ranges between 0.1 mm and 3.0 mm. The porous diffusion member (32) has a shape matching the hollow (313), such that the porous diffusion member (32) can be properly restricted in the hollow (313) in without any gaps. Edges of the porous diffusion member (32) are engaged with the outer skeleton (311) and the inner skeleton (312), and the lower surface of the porous diffusion member (32) can be supported by at least the support member (3121) to prevent the porous diffusion member (32) from detaching. In other possible embodiments, the support member (3121) may be omitted, such that the porous diffusion member (32) is restricted by only the outer skeleton (311) and the inner skeleton (312). The porous diffusion member (32) is fundamentally formed by means of sintering a porous powder at a high temperature, for example, a temperature ranging between 210° C. and 240° C.; however, the present invention is not limited to the above example. The porous powder may refer to a type of powder that can be formed into a porous sintered block by high temperature molding. In a preferred embodiment, the thickness of the porous diffusion member (32) ranges between 0.1 mm and 0.3 mm, and a diameter of each pore or an average pore diameter of the porous diffusion member ranges between 0.1 μm and 10 μm.

FIG. 2F and FIG. 2G are further enlarged diagrams of the structure in the hollow (313) from top and bottom perspectives, respectively. A coupling member (315) is a rib structure extending at the inner side of the outer skeleton (311) and the inner side of the inner skeleton (312), that is, the coupling member (315) extends along the edges of the hollow (313). As shown, the coupling member (315) and the upper surface of the frame (31) are a discontinuous stepped structure, and the support member (121) a bridge connection structure extending from the coupling member (315).

Again referring to FIG. 2B, the bottom surface of the recess (222) may have one or more air passages (223) which may have a shape corresponding to the hollow (313); however, the present invention is not limited to the above example. The air passage (223) penetrates the cover (22) and communicates the inner side and the outer side of the cover (22). As previously described, the plurality of connecting members (224) are provided on the bottom surface of the recess (222), and the frame (31) can be fixed in the recess (222) of the cover (22) by a locking member once the connecting members (314) of the frame (31) are aligned with the connecting members (224) in the recess (222).

FIG. 2H shows a member diagram along the line A-A in FIG. 2D according to another embodiment. Different from the above embodiment in which the lower surface of the porous diffusion member (32) falls on the coupling member (315) and the support member (3121), a coupling member (316) and the upper and lower surfaces of the inner skeleton (312) of this variation example shown form a stepped structure, and the coupling member (316) similarly has the bridge connection structure as the support member (3121). When the porous powder is filled in the hollow (313), sintered and molded, the coupling member (316) and the bridge connection structure thereof are both embedded into the porous diffusion member (32), thereby preventing the porous diffusion member (32) from detaching. FIG. 2I shows a member diagram along the line B-B in FIG. 2D according to another embodiment, and shows a coupling member (316) without a bridge connection structure. In another variation example in FIG. 2J, a coupling member (316′) may be configured to close to a surface of the inner skeleton (312), so as to prevent, by the friction between the edges of the porous diffusion member (32) and the coupling member (316′), the porous diffusion member (32) from detaching. In another variation example in FIG. 2K, a coupling member (316″) may be a rib having a sloped surface. These coupling members (315, 316, 316′ and 316″) may be altogether embedded or engaged with the porous diffusion member (32) during sintering and molding of the porous diffusion member (32). In other possible variation examples, the porous diffusion member (32) may be separately molded and then assembled to the frame (31). The coupling members (315, 316, 316′ and 316″) may be continuous structures extending at the inner skeleton (312) and the inner side of the outer skeleton (311), that is, extending along the outline of the hollow (313). It should be noted that, the coupling members (315, 316, 316′ and 316″) may also be discontinuous structures, and the numbers of the coupling members (315, 316, 316′ and 316″) may also have different combinations. Alternatively, the size of the coupling member may be appropriately designed, such that a pre-formed porous diffusion member can be engaged with the coupling members in the hollow or be removed from the hollow by an appropriate force. Thus, the porous diffusion member can be more easily replaced. A sealing member can be provided between the porous diffusion member (32) and the frame (31) to prevent a gas from leaking around the porous diffusion member (32).

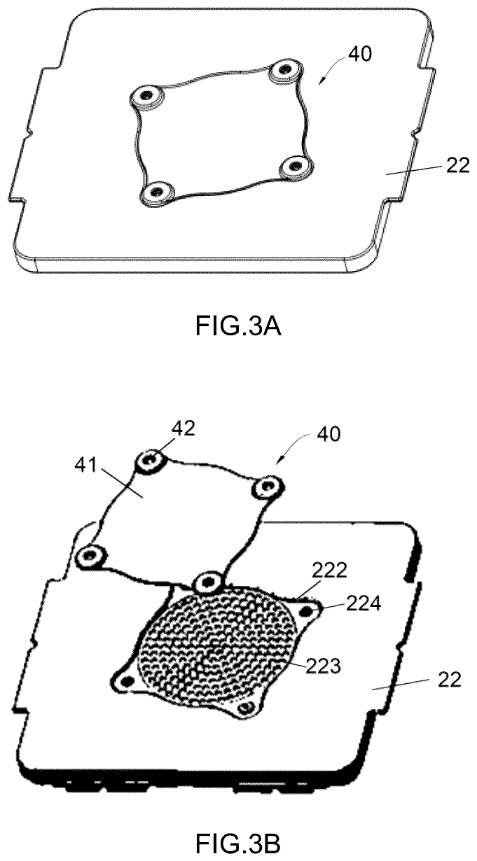

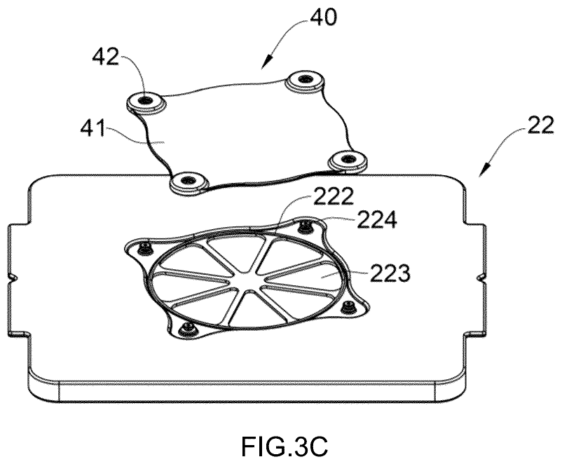

FIG. 3A and FIG. 3B show a gas filter device (40) according to a second embodiment of the present invention. The gas filter device (40) is detachably connected to a cover (22) of a reticle carrier. Although a base of the reticle carrier is not shown, related details can be understood by a person skilled in the art with reference to the base (21) in FIG. 1.

The gas filter device (40) is integrally formed primarily by a panel (41) and a plurality of connecting members (42). The panel (41) fundamentally has an upper surface, a lower surface and a thickness. The panel (41) may have a consistent thickness or a varying thickness. Similarly, the thickness ranges between 0.1 mm and 3.0 mm. The panel (41) fundamentally has a shape (for example, a circle) with an area sufficient to cover all of the air passages (223). The air passages (223) of this embodiment are through holes penetrating the internal accommodation space of the reticle carrier, and the structural design of the air passages (223) may be a plurality of radial through holes equidistant from a center position of the cover (22); however, the present invention does not limit the geometric design pattern of the through holes. As shown in FIG. 3C, the air passages (223) provided by another variation are similarly in a centrally symmetric distribution as the configuration in the FIG. 2B. The connecting members (42) are configured around the panel (41), and serve as parts that withstand stress and thus have a larger thickness. A connecting part of the panel (41) and the connecting members (42) may be provided with a stiffener structure to thereby prevent breakage between the connecting members (42) that withstand stress and the panel (41). Similarly, the connecting members (42) may be configured to be fixed to the corresponding connecting members (224) of the recess (222) by locking members (for example, screws).

Although not shown in the drawings, an appropriate sealing means such as a sealing ring or a sealing pad may be provided between the porous diffusion member (32) and the air passages (223) to prevent gas leakage from gaps. Although a single-layer porous diffusion member is exhibited in the above embodiments, the present invention is not limited to a single-layer configuration. For example, at least two layers of porous diffusion members may be used and air or a conventional filter membrane may be present between the two. In addition, the porous diffusion member of the present invention is not limited to being mounted or removed by using locking members, and other connecting means such as inserting or embedding are also feasible, given that the porous diffusion member can be positioned and communicate with the air passages of the cover. For example, the porous diffusion member can be located on top sides (as the above embodiment) of the air passages, or may be mounted on an inner side of the cover and be located on bottom ends of the air passages. Alternatively, the porous diffusion member may be filled in a predetermined form in the air passages. Thus, regardless of whether a gas enters the internal accommodation space from the outside of the reticle carrier, or a gas is released to the outside of the reticle carrier from the internal accommodation space, micro particles in the gas are effectively blocked and filtered by the porous diffusion member.

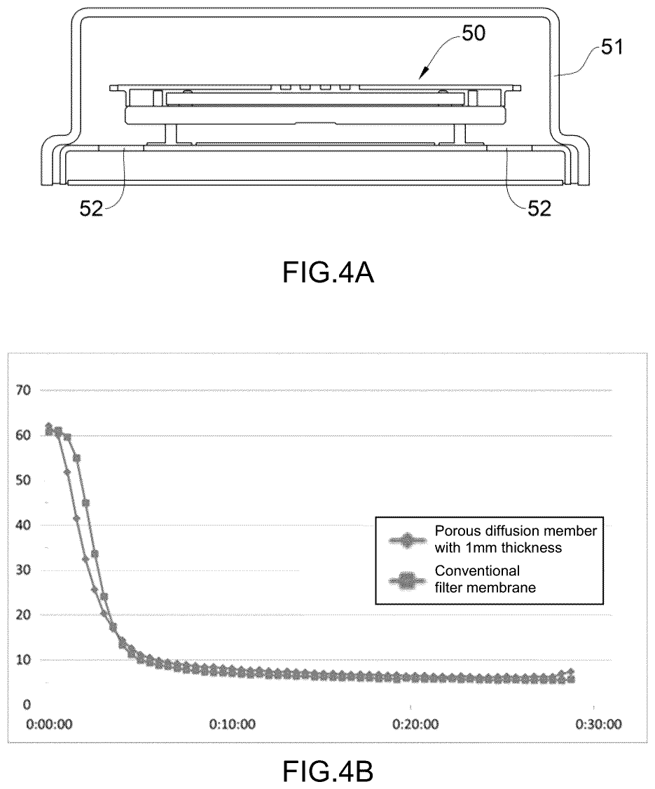

FIG. 4A shows a configuration example of a gas backfilling experiment. In the experiment, a reticle carrier under test (for example, an inner pod of a dual pod) is placed in a gas backfill space, for example, an accommodation space defined by an outer pod of a dual pod. As shown in FIG. 4A, the reticle carrier under test (50) is placed in an outer pod (51), that is, the configuration of a dual pod. A base of the outer pod (51) has one or more intake passages (52), which may be connected to a gas supply system (not shown) and receive a gas from a gas source, for example, a dry gas, so that the accommodation space of the outer pod (51) can be filled by the dry gas. In reticle storage, the dry gas is capable or reducing the humidity of a carrier accommodation space and preventing reticles from contamination of moisture. Thus, by effectively filling the dry gas into the reticle accommodation space, the humidity of a storage environment can be quickly reduced.

FIG. 4B is a diagram of an example of a gas backfilling experiment, showing dropping of humidity levels a reticle carrier of the present invention and a conventional reticle carrier, where the horizontal axis represents time and the vertical axis represents the normalized humidity. The experiment fills a dry gas at a predetermined flow into a gas backfill space defined by the outer pod (51) through the intake passages (52). The dry gas is diffused in the outer pod (51) and enters the accommodation space through a filter mechanism of the reticle carrier under test (50), and one or more humidity sensors may be configured in the reticle carrier under test (50) to monitor and detect humidity changes in the accommodation space in the reticle carrier under test (50). When the experiment performed on the reticle carrier under test (50) in FIG. 4A is carried out using a conventional filter membrane and the porous diffusion member of the present invention, it is observed that the porous diffusion member having a thickness of 1 mm exhibits a humidity drop starting time earlier than that of the conventional filter membrane, and this demonstrates that the porous diffusion member of the present invention renders less hinder with respect to the flow of the dry gas.

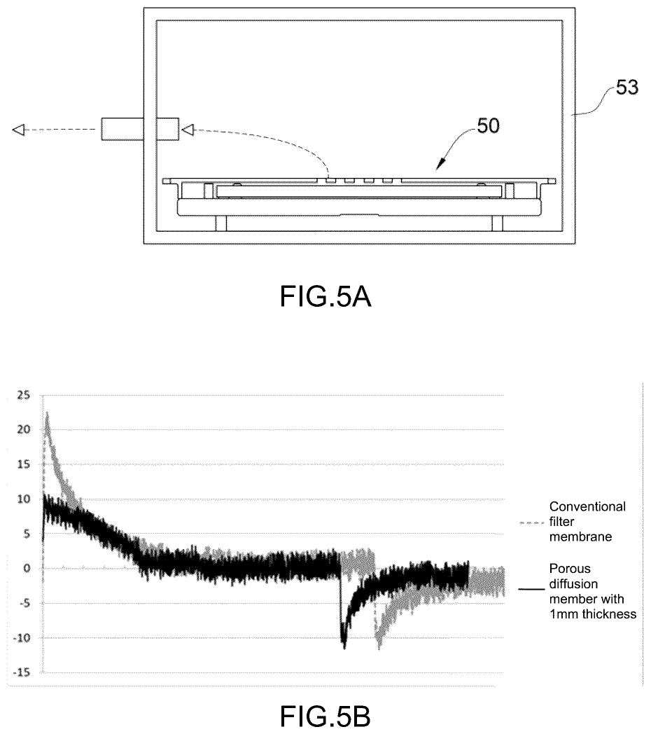

FIG. 5A shows a configuration example of a gas exhaustion experiment. In the experiment, the reticle carrier under test (50) is placed in a test cavity (53). The test cavity (53) has an initial pressure, and the accommodation space in the reticle carrier under test also has a consistent pressure. The test cavity (53) can be connected to an exhaust system to exhaust the gas in the test cavity (53) to an almost vacuum state, and at the same time, the gas in the accommodation space of the reticle carrier under test is also exhausted through a filter interface of the carrier. However, during the actual process of exhaustion, the test cavity (53) and the accommodation space in the reticle carrier under test (50) exhibit a pressure difference in between, that is, a pressure difference between the inside and the outside of the reticle carrier under test (50). In the experiment, one or more pressure sensors are respectively configured in the test cavity (53) and the accommodation space of the reticle carrier under test (50) to thereby observe pressure changes during the process of exhaustion. Changes in the pressure difference are common for reticle carriers, and this is because that reticle carriers are transported in different process environments of different pressures. However, the reticle carriers sometimes need to be operated in a state of balance between inner and outer pressures. Thus, the time needed for achieving a balance between inner and outer pressures of a reticle carrier affects the overall process time.

FIG. 5B is a diagram of an example of a gas backfilling experiment, showing changes in pressure differences of a reticle carrier of the present invention and a conventional reticle carrier, where the horizontal axis represents time and the vertical axis represents the normalized pressure difference. The experiment is carried out by using a reticle carrier having the porous diffusion member (having a thickness of 1 mm) of the present invention and a reticle carrier having a conventional filter membrane. The pressure difference between the inside and outside of the carrier using the porous diffusion member of the present invention has smaller changes, and the timing of achieving a stable pressure difference is also earlier, and this demonstrates that the flow of a gas has less hinder between the test cavity (53) and the accommodation space of the reticle carrier under test (50) through the porous diffusion member of the present invention, proving that the porous diffusion member of the present invention has better air permeability.

Moreover, under an appropriately controlled thickness, the porous diffusion member of the present invention provides excellent filtering performance in addition to air permeability better than that of a conventional filter membrane. In a filter experiment, when the diameter size of each hole or an average diameter size of the porous diffusion member is more than 0.1 μm (but less than 10 μm), the filter effect of the porous diffusion member may reach as high as more than 99%. In the experiment, measurement is conducted during a gas exchange process when a predetermined particle source is provided, and a percentage of a ratio of final particles having passed through the “porous diffusion member” is used the filter effect.

In conclusion, the gas filer device of the present invention uses a non-flexible porous diffusion member as a filter means, so that during gas exchange, a reticle carrier having the porous diffusion member of the present invention provides a filtering function, and is further capable of preventing from producing contaminating micro particles caused by vibration and friction of the porous diffusion member, thereby solving the technical drawbacks of a conventional filter membrane. Moreover, the gas filter device is detachably connected to a reticle carrier, and the porous diffusion member is also detachably connected to the gas filter device. Thus, the gas filter device and the porous diffusion member can be replaced after a period of use.

Although certain details are used to describe the present invention as above for better understanding, it is to be understood that certain changes and modifications may be implemented within the scope of protection of the claims. Therefore, the embodiments above are intended for illustration purposes, and are not to be construed as limitations. Moreover, the present invention is not restrained by the details given in the description, and equivalent modifications made be made without detaching from the field and spirit of the appended claims.

What is claimed is:

1. A gas filter device, detachably mounted onto a reticle carrier, the gas filter device comprising:
a frame, having at least one hollow, the frame detachably connected to the reticle carrier; and
at least one porous diffusion member, having a shape matching the at least one hollow of the frame to thereby stably securing the at least one porous diffusion member to the frame, such that an internal accommodation space of the reticle carrier communicates with an outside of the reticle carrier through the at least one porous diffusion member.

2. The gas filter device according to claim 1, wherein the frame has a plurality of hollows in an arrangement of central symmetric.

3. The gas filter device according to claim 1, wherein the frame has an outer skeleton and at least one inner skeleton connected to the outer skeleton, the outer skeleton and the inner skeleton define the hollow in between, the outer skeleton comprises a plurality of connecting members which individually coordinates with a locking member, such that the outer skeleton is detachably connected to a cover of the reticle carrier, and the inner skeleton engages with the porous diffusion member.

4. The gas filter device according to claim 3, wherein an inside of the inner skeleton comprises at least one coupling member, which restricts edges of the porous diffusion member to prevent the porous diffusion member from detaching from the hollow.

5. The gas filter device according to claim 4, wherein the inside of the inner skeleton comprises at least one support member connected to the coupling member, and the support member is embedded in the porous diffusion member to prevent the porous diffusion member from detaching from the hollow.

6. The gas filter device according to claim 4, wherein the at least one coupling member and an upper surface or a lower surface of the frame appear as a discontinuous stepped structure, and the porous diffusion member is engaged with the least one coupling member of the inner skeleton by means of sintering.

7. The gas filter device according to claim 1, wherein the at least one porous diffusion member has an upper surface, a lower surface, and a thickness extending between the upper surface and the lower surface, and the thickness ranges between 0.1 mm and 3.0 mm.

8. The gas filter device according to claim 1, wherein the at least one porous diffusion member is formed by means of sintering a porous powder at a sintering temperature ranging between 210° C. and 240° C.

9. The gas filter device according to claim 1, wherein a diameter of each pore or an average pore diameter of the at least one porous diffusion member ranges between 0.1 μm and 10 μm.

10. A reticle carrier, comprising a cover, a base, and the gas filter device according to claim 1, wherein the gas filter device is detachably connected to the cover.

11. A gas filter device, detachably mounted onto a reticle carrier, the gas filter device comprising:
a porous diffusion member, having a panel and a plurality of connecting members located on an outer edge of the panel, the plurality of connecting members respectively coordinating with a plurality of locking members such that the porous diffusion member is detachably connected to the reticle carrier by the plurality of connecting members;
wherein, an internal accommodation space of the reticle carrier communicates with an outside of the reticle carrier through the porous diffusion member, and the panel and the plurality of connecting members of the porous diffusion member are integrally formed.

12. The gas filter device according to claim 10, wherein the panel of the porous diffusion member has an upper surface, a lower surface, and a thickness extending between the upper surface and the lower surface, and the thickness ranges between 0.1 mm and 3.0 mm.

13. The gas filter device according to claim 10, wherein the panel and the plurality of connecting members of the porous diffusion member is formed by means of sintering a porous powder at a sintering temperature ranging between 210° C. and 240° C.

14. The gas filter device according to claim 10, wherein a diameter of each pore or an average pore diameter of the porous diffusion member ranges between 0.1 μm and 10 μm.

15. A reticle carrier, comprising:
a cover and a base, defining an accommodation space; and
a gas filter device, detachably mounted onto the cover, the gas filter device comprising:
at least one porous diffusion member, detachably connected to the cover, such that the accommodation space communicates with an outside of the reticle carrier through the at least one porous diffusion member.

16. A reticle carrier, comprising:
a cover and a base, defining an accommodation space; and
a frame, detachably mounted onto the cover, the frame comprising:
an outer skeleton and an inner skeleton, defining at least one hollow, the hollow for being filled with a porous diffusion member formed by sintering a porous powder.
